(19) United States
(12) Patent Application Publication
(10) Pub. No.: US 2025/0287540 A1
(43) Pub. Date: Sep. 11, 2025

(54) ELECTRONIC APPARATUS

(71) Applicant: CANON KABUSHIKI KAISHA, Tokyo (JP)

(72) Inventor: NAGISA YANAGIBASHI, Kanagawa (JP)

(21) Appl. No.: 19/043,907

(22) Filed: Feb. 3, 2025

(30) Foreign Application Priority Data
Mar. 11, 2024 (JP) 2024-037311

(51) Int. Cl. H05K 7/20; H04N 23/52

(52) U.S. Cl. CPC H05K 7/2039; H04N 23/52

(57) ABSTRACT

An electronic apparatus includes a heat generator, a heat radiating member configured to radiate heat from the heat generator, and a thermally conductive member disposed between the heat generator and the heat radiating member. The thermally conductive member has a first area, a second area, and a third area having a curved shape and disposed between the first area and the second area. The first area and the second area of the thermally conductive member are attached to one of the heat generator and the heat radiating member.

### BACKGROUND

### Technical Field

The present disclosure relates to an electronic apparatus.

### Description of Related Art

Conventionally, there is known an image pickup apparatus that includes an image stabilizing mechanism configured to displacing an image sensor in a two-dimensional direction orthogonal to the optical axis in order to suppress image blur caused by a user's hand shake. Such an image pickup apparatus is to exhibit sufficient heat radiating performance because the heat generated in the image sensor and circuit board constituting the image stabilizing mechanism affects image quality. However, if a heat radiating member with high rigidity is attached for heat radiation, a reaction force is generated when the image sensor is displaced in a two-dimensional direction and places a load on the image stabilizing mechanism.

Japanese Patent Laid-Open No. 2009-284414 discloses a structure that includes a ring-shaped heat radiation sheet between a support plate mounted with an image sensor and a heat radiating plate fixed at a position opposite to the support plate. The ring-shaped heat radiation sheet is flexible and thus can perform heat radiation without placing a load on the image stabilizing mechanism.

However, in the structure disclosed in Japanese Patent Laid-Open No. 2009-284414, a contact surface of the heat radiation sheet that is to contact the support plate mounted with the image sensor changes due to the two-dimensional displacement amount of the image sensor and gravity, and may reduce the heat radiating effect.

### SUMMARY

An electronic apparatus according to one aspect of the disclosure includes a heat generator, a heat radiating member configured to radiate heat from the heat generator, and a thermally conductive member disposed between the heat generator and the heat radiating member. The thermally conductive member has a first area, a second area, and a third area having a curved shape and disposed between the first area and the second area. The first area and the second area of the thermally conductive member are attached to one of the heat generator and the heat radiating member.

Further features of various embodiments of the disclosure will become apparent from the following description of embodiments with reference to the attached drawings.

### BRIEF DESCRIPTION OF THE DRAWINGS

FIGS. 1A and 1B are external perspective views of an electronic apparatus according to a first embodiment.

FIG. 2 is a block diagram of the electronic apparatus according to the first embodiment.

FIG. 3 is an exploded perspective view of the electronic apparatus according to the first embodiment.

FIGS. 4A and 4B are exploded perspective views of an imaging unit according to the first embodiment.

FIGS. 5A to 5D are schematic diagrams of the thermally conductive sheet according to the first embodiment.

FIG. 6 is an internal configuration diagram of an electronic apparatus according to a second embodiment.

FIG. 7 is an exploded perspective view of an electronic apparatus according to a third embodiment.

FIG. 8 is a sectional view of a thermally conductive sheet according to the third embodiment.

### DETAILED DESCRIPTION

Referring now to the accompanying drawings, a detailed description will be given of embodiments according to the disclosure.

### First Embodiment

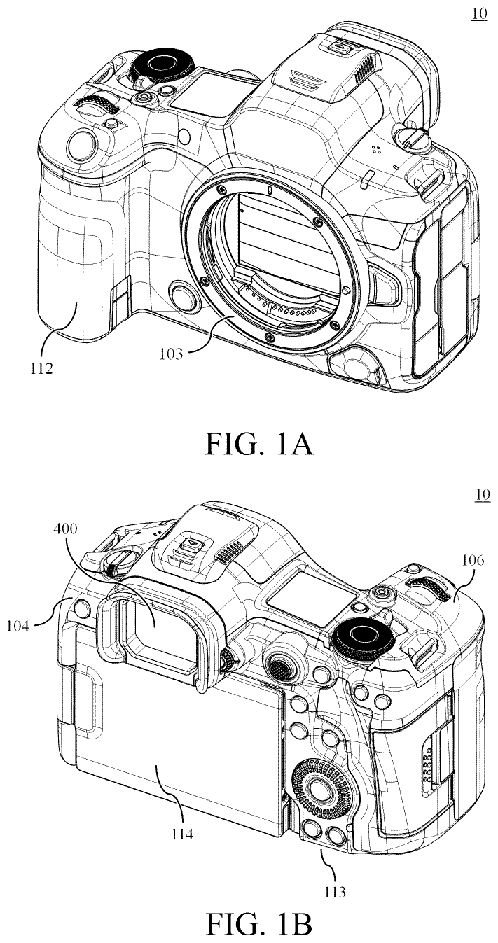

Referring now to FIGS. 1A and 1B, a description will be given of a camera body (image pickup apparatus, electronic apparatus) 10 according to this embodiment. FIG. 1A is an external perspective view of the camera body 10 viewed from the front side, and FIG. 1B is an external perspective view of the camera body 10 when viewed the rear side.

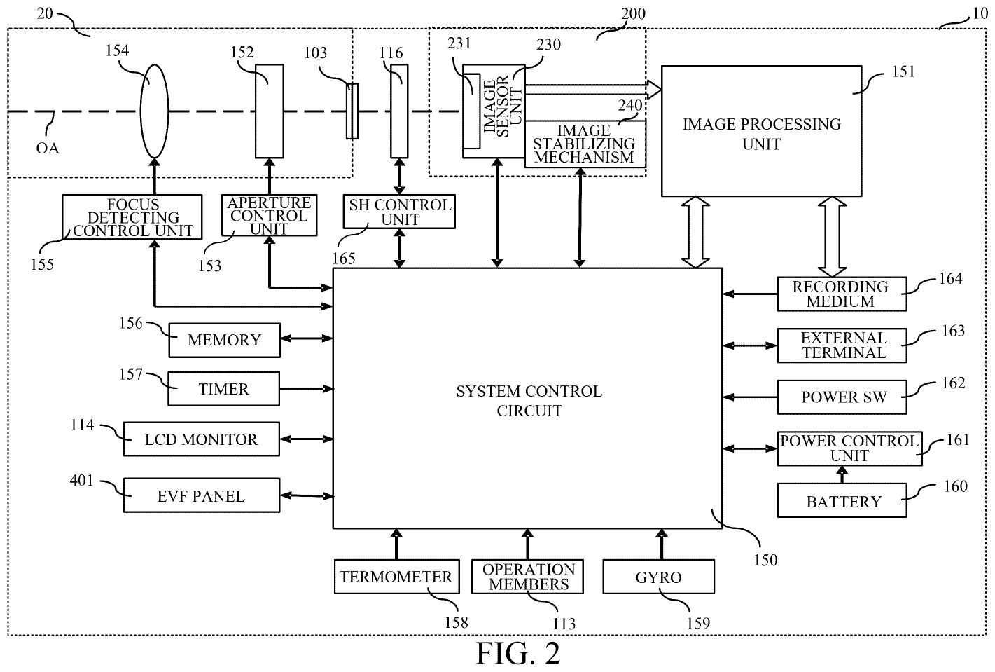

In FIG. 1A, the camera body 10 includes a mount 103 for detachably mounting a lens apparatus (interchangeable lens) 20 (see FIG. 2). A grip portion 112 for a user to hold the camera body 10 is provided on the right side of the mount 103. Each embodiment describes a lens interchangeable type camera in which a lens apparatus (interchangeable lens) is attachable to and detachable from the image pickup apparatus as the camera body 10 (camera body 10a), but is not limited to this example. Each embodiment is also applicable to an image pickup apparatus in which the camera body and the lens apparatus are integrated.

In FIG. 1B, a plurality of operation members 113, a liquid crystal display (LCD) monitor 114, and an electronic viewfinder (EVF) unit 400 are attached to a rear cover 104. The LCD monitor 114 displays various setting screens, captured images, live-view images, etc. of the camera body 10. The EVF unit 400 is an eye approachable viewfinder, and displays various setting screens, captured images, live-view images, etc. of the camera body 10. The plurality of operation members 113 are attached to a top cover 106. The operation members 113 can be used to power on and off the camera body 10, start imaging, and change various settings.

Referring now to FIG. 2, a description will be given of the electrical configuration and operation of the camera body 10. FIG. 2 is a block diagram that illustrates a schematic diagram of the main electrical configuration of the camera body 10.

The lens apparatus 20 includes an optical system (imaging optical system) that includes a lens 154 and an aperture stop (diaphragm) 152. The position of the lens 154 in a direction along the optical axis OA (optical axis direction) is controlled by a focus detection control unit 155. An aperture control unit 153 controls an aperture amount of the aperture stop 152. Light incident on the lens 154 passes through the aperture stop 152 and a shutter 116 and is focused as an optical image on the imaging surface of an image sensor 231. The shutter 116 is a light shielding member. The opening and closing operation of the shutter 116 is controlled by a shutter (SH) control unit 165, and thereby an exposure amount to the image sensor 231 is controlled.

The imaging unit 200 includes an image sensor unit 230 and an image stabilizing mechanism 240. The image sensor unit 230 includes the image sensor (electronic component, heat generator) 231. The image sensor 231 includes a complementary metal oxide semiconductor (CMOS) image sensor or a charge coupled device (CCD) image sensor, photoelectrically converts an optical image formed by the imaging optical system, and outputs image data. The image stabilizing mechanism 240 corrects image blur by driving the image sensor 231 in a two-dimensional direction orthogonal to the optical axis OA according to a shake amount of the camera body 10 detected by a gyro (sensor) 159.

A system control circuit 150 is a control unit configured to control the entire camera body 10. A memory 156 is a storage unit storing constants and programs for the operation of the system control circuit 150. A timer 157 measures the time for various operations. The system control circuit 150 is used as a determining unit and a control unit in various operations of the camera body 10. The system control circuit 150 also controls the shutter 116, the lens 154, and the aperture stop 152 based on the results of calculations by an image processing circuit 151 on image data captured by the image sensor 231, to perform autofocus (AF) processing and auto-exposure (AE) processing. The memory 156 further stores a holding state of the image sensor unit 230 by the image stabilizing mechanism 240. An external terminal 163 is a terminal for electrically connecting to an external device, and information can be sent and received between the system control circuit 150 and the external device via the external terminal 163.

The LCD monitor 114 and the electronic viewfinder (EVF) panel 401 display image data captured by the image sensor 231, as well as settings and information regarding imaging. A thermometer 158 measures the temperature of the heat generator such as the image sensor 231, the LCD monitor 114, and the EVF panel 401. The operation members 113 include various buttons and switches that are operable by the user, and used to select and set various functions in performing imaging, playback, communication, and the like, and to give instructions regarding imaging and playback. A power switch 162 can switch between the power-on state and the power-off state of the camera body 10.

A power supply control unit 161 includes a battery detection circuit, a DC/DC converter, and a switch circuit that switches between blocks to which electricity is applied. It detects the type and remaining charge of the battery 160 that serves as the power source for the camera body 10, and supplies the required voltage to each unit, including a recording medium 164, for a necessary period based on the detection results and instructions from the system control circuit 150.

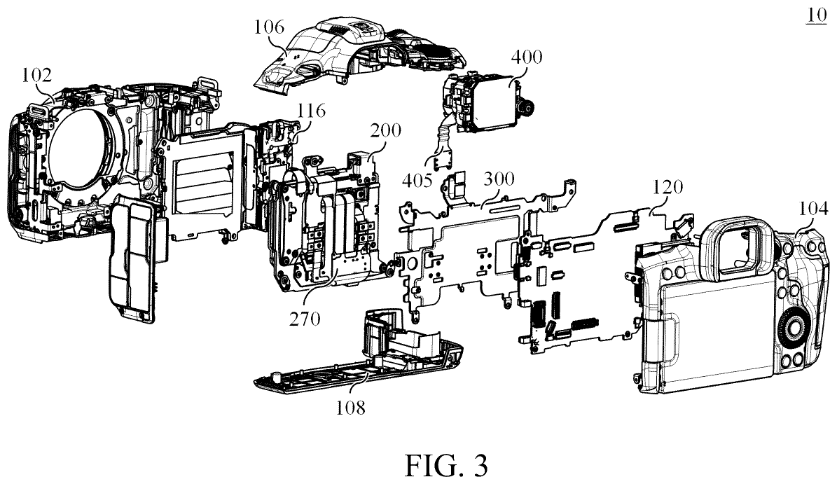

Referring now to FIG. 3, the internal structure of the camera body 10 will be described. FIG. 3 is an exploded perspective view of the camera body 10. The camera body 10 is covered by a front base 102, a top cover 106, a rear cover 104, and a bottom cover 108. These parts constitute the exterior member of the camera body 10.

Provided inside the exterior member, the shutter 116 are the imaging unit 200, a heat radiating sheet metal (heat radiating member) 300, a main board 120, and the EVF unit 400. The heat radiating sheet metal 300 is disposed at a position opposite to the imaging unit 200, which is a heat generator (opposite surface), and radiates heat from the imaging unit 200. The front base 102 is formed, for example, of magnesium die casting or resin. Various electronic components such as electronic elements constituting the system control circuit 150 or an image processing circuit 151, and a connector for mounting the recording medium 164 are mounted on the main board 120. The main board 120 is fixed to the front base 102 and the heat radiating sheet metal 300 with screws.

A flexible printed circuit (FPC) board 270 electrically connects the imaging unit 200 and the main board 120. An image signal from the imaging unit 200 is transmitted to the main board 120 via the FPC board 270.

The imaging unit 200 consumes a large amount of power, particularly in the camera body 10. Thus, the imaging unit 200 generates a large amount of heat and is prone to temperature rise. However, if the temperature of the imaging unit 200 exceeds a predetermined temperature, it will affect the captured image, so the temperature of the imaging unit 200 is to be kept below the predetermined temperature. The imaging unit 200 is fixed to the front base 102 with screws. In addition, by connecting a thermally conductive sheet 501 (described later) to the heat radiating sheet metal 300, the heat from the imaging unit 200 can be radiated to the front base 102 and the heat radiating sheet metal 300.

The FPC board 405 electrically connects the EVF unit 400 and the main board 120. The EVF unit 400 displays captured image data, as well as settings and information regarding imaging, from the main board 120 via the FPC board 405.

The EVF unit 400 has a large amount of self-heat generation because it includes a display device. In addition, the EVF unit 400 is susceptible to heat generation from electronic components mounted on the main board 120 via the FPC board 405, and so its temperature is likely to rise. By connecting a thermally conductive sheet 410 (described later) to the heat radiating sheet metal 300, the heat from the EVF unit 400 can be radiated to the heat radiating sheet metal 300.

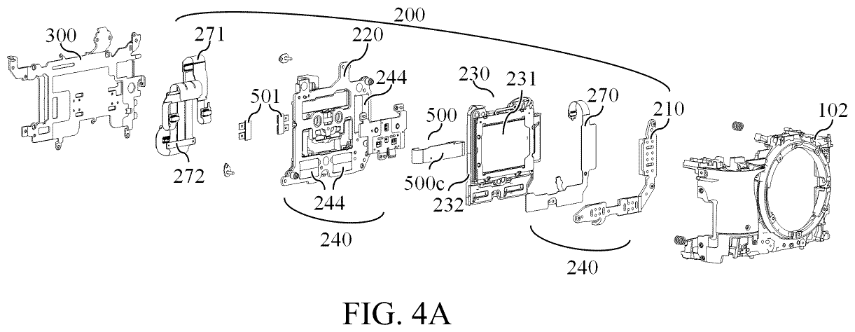

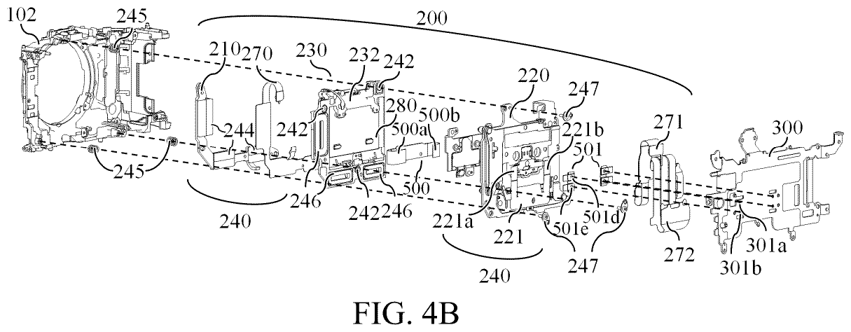

Referring now to FIGS. 4A, 4B, and 5A to 5D, a description will be given of the heat radiating structure for the image stabilizing mechanism 240 and image sensor 231 of the imaging unit 200. FIG. 4A is an exploded perspective view of the imaging unit 200 viewed from the front side, and FIG. 4B is an exploded perspective view of the imaging unit 200 viewed from the rear side. FIG. 5A is a perspective view of the thermally conductive sheet 501, FIG. 5B is a sectional view of the thermally conductive sheet 501, FIG. 5C is a sectional view of the thermally conductive sheet 501 in a pressed state, and FIG. 5D is a perspective view of a state in which a plurality of thermally conductive sheets 501 are stacked.

The imaging unit 200 includes a front plate 210, a rear plate 220, and an image sensor unit 230 disposed between the front plate 210 and the rear plate 220. Each of the front plate 210 and the rear plate 220 includes a metal plate. The imaging unit 200 is fixed to the front base 102 with three screws 247, and three coil springs 245 are disposed between the imaging unit 200 and the front base 102. The imaging unit 200 is supported displaceably (movably) in the optical axis direction by the tightening amounts of the three screws 247 and the three coil springs 245, and the tilt of the image sensor 231 relative to the front base 102 can be adjusted.

The image sensor unit 230 includes the image sensor 231 and an image sensor holder 232 configured to hold the image sensor 231. Between the image sensor holder 232 and the rear plate 220, three balls 242 are disposed around the image sensor 231 so as to surround the optical axis OA. These three balls 242 roll freely, so that the image sensor unit 230 is held between the front plate 210 and the rear plate 220 swingably in a direction orthogonal to the optical axis direction (within a plane orthogonal to the optical axis OA).

A plurality of magnets 244 are disposed on the front plate 210 and the rear plate 220. On the other hand, a plurality of coils 246 are disposed opposite to the magnets 244 on the image sensor holder 232.

The FPC board 270 supplies power to the magnets 244. This power supply controls the swing of the image sensor unit 230 by utilizing the repulsive and attractive forces between the magnetic field generated in the coils 246 and the magnets 244. In general, the image stabilizing mechanism 240 controls the image sensor unit 230 so as to maintain it at the imaging center position, and also controls the image sensor unit 230 to move in a direction that cancels image shake of the camera body 10 caused by the user.

The image sensor 231 is mounted on the imaging board 280, and the imaging board 280 and the main board 120 are electrically connected by imaging FPC boards 271 and 272. The imaging FPC boards 271 and 272 have wirings that transmit the imaging signal output from the image sensor 231 and the control signal required to drive the image sensor 231, and each signal is sent to the main board 120. The imaging FPC boards 271 and 272 also supply power to drive the image sensor 231.

The thermally conductive sheets 500 and 501 are, for example, graphite sheets with high heat radiating performance. A thermally conductive sheet fixing unit 221 is fixed to the rear plate 220 with screws. The thermally conductive sheet 500 connects the imaging board 280 mounted with the image sensor 231 and the thermally conductive sheet fixing unit 221. In the thermally conductive sheet 500, contact portions 500a and 500b are adhered to attachment surfaces 221a and 221b, respectively, and a contact portion 500c is adhered to the imaging board 280, via an adhesive such as double-sided tape. A distance between the contact portions 500a and 500b and a distance between the contact portions 500b and 500c are set to a sufficient length so that the thermally conductive sheet 500 follows the displacement of the image sensor unit 230.

The thermally conductive sheet 501 is a thermally conductive member disposed between the imaging unit 200 and the heat radiating sheet metal 300, and is disposed so that the imaging unit 200 and the heat radiating sheet metal 300 are in thermal contact with each other. In this embodiment, the thermally conductive sheet 501 connects the thermally conductive sheet fixing unit 221 and the heat radiating sheet metal 300.

The thermally conductive sheet 501 has an attachment area (first area) 501a and an attachment area (second area) 501b at both ends, and a curved area (third area having a curved shape) 501c between them. The curved area 501c includes cylindrically shaped areas 501c1 and an area 501c2 in contact with the imaging unit 200 (thermally conductive sheet fixing unit 221).

The thermally conductive sheet 501 is attached to a surface (surface of the heat radiating sheet metal 300) orthogonal to the optical axis OA in each of the attachment areas 501a and 501b. The attachment areas 501a and 501b of the thermally conductive sheet 501 are folded back at folding back portions 501f relative to the curved area 501c. The attachment areas 501a and 501b are attached to the heat radiating sheet metal 300 with an adhesive such as double-sided tape. At this time, the thermally conductive sheet 501 is positioned by aligning holes 501d and 501ₑ in the thermally conductive sheet 501 with holes 301a and 301b in the heat radiating sheet metal 300. The curved area 501c has a sufficient length to contact the thermally conductive sheet fixing unit 221.

The thermally conductive sheet 501 may be disposed in the opposite manner to the above, with the attachment areas 501a and 501b adhered to the thermally conductive sheet fixing unit 221 and the curved area 501c in contact with the heat radiating sheet metal 300 (other related members may also be configured in the opposite manner). That is, the attachment areas 501a and 501b of the thermally conductive sheet 501 may be attached to one of the imaging unit 200 (thermally conductive sheet fixing unit 221) and the heat radiating sheet metal 300, and the curved area 501c may be in contact with the other of the imaging unit 200 and the heat radiating sheet metal 300.

As illustrated in FIG. 5D, the thermally conductive sheet 501 has an Ω shape (curved shape) when viewed from a direction orthogonal to the optical axis direction (X-axis direction). Thereby, the thermally conductive sheet 501 becomes flexible, follows the displacement amount of the imaging unit 200 in the optical axis direction, and maintains a contact state with the thermally conductive sheet fixing unit 221. In addition, the imaging unit 200 can be adjusted in the optical axis direction without applying a load to the three coil springs 245.

At least a portion of the area between the curved area 501c and the attachment areas 501a and 501b is adhered by a double-sided tape (adhesive member) 502. In the thermally conductive sheet 501, the curved area 501c has a cylindrical shape that is uniform in the Y-axis direction relative to the attachment areas 501a and 501b. Thereby, the thermally conductive sheet 501 can maintain the Ω shape (curved shape) against the displacement of the imaging unit 200 or gravity, and the contact surface of the thermally conductive sheet fixing unit 221 can be stable.

The heat radiating sheet metal 300 has clearance grooves (openings) 302a and 302b for allowing at least a portion of the thermally conductive sheet 501 to escape. Therefore, even if the heat radiating sheet metal 300 and the thermally conductive sheet fixing unit 221 are close to each other and the thermally conductive sheet 501 is pressed (crushed), the thermally conductive sheet 501 can escape in the clearance grooves 302a and 302b, and does not develop a crease, allowing it to return to its Ω shape.

To further enhance the heat radiating effect, the thermally conductive sheet 501 may be configured by stacking multiple thermally conductive sheets or by providing them at multiple locations. As illustrated in FIG. 5D, multiple conductive sheets may be arranged in a cross-like manner to increase the contact area.

The above structure according to this embodiment can radiate the heat generated by the image sensor 231 to the heat radiating sheet metal 300 through the thermally conductive sheets 500 and 501 without applying a load to the swing control of the imaging unit 200.

### Second Embodiment

Next, a second embodiment of the present disclosure will be described. The first embodiment has discussed an example heat radiation configuration from the image sensor 231 to the heat radiating sheet metal 300. On the other hand, this embodiment will discuss an example heat radiation configuration from the image sensor 231 to an exterior member. Those elements in this embodiment, which are corresponding elements in the first embodiment, will be designated by the same reference numerals, and a detailed description thereof will be omitted.

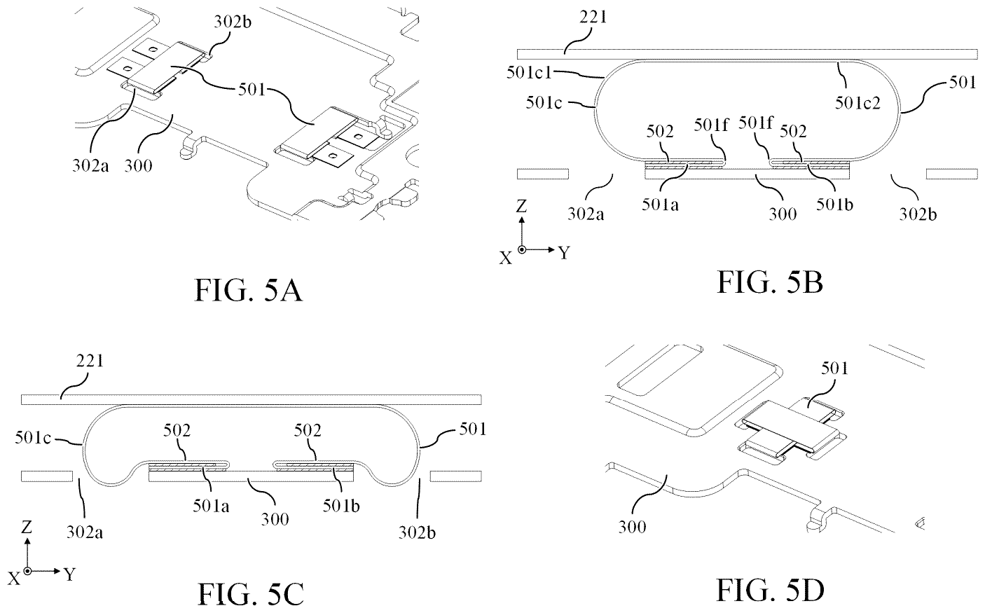

Referring now to FIG. 6, a description will be given of the configuration of the thermally conductive sheet 600 according to this embodiment. FIG. 6 is an internal configuration diagram of a camera body (image pickup apparatus, electronic apparatus) 10a having a thermally conductive sheet 600 according to this embodiment. The thermally conductive sheet 600 is a thermally conductive member having an attachment area (first area) 600a, an attachment area (second area) 600b, and a curved area (curved third area) 600c between the attachment areas 600a and 600b. The attachment areas 600a and 600b are attached to the periphery of the image sensor unit 230 by an adhesive such as double-sided tape. The number, the position in the XY direction, or the length of the curved area 600c of the thermally conductive sheet 600 may be changed as appropriate according to the load of the swing control of the image sensor unit 230.

A side plate 111 constituting an exterior member is attached to a side surface of the front base 102 constituting the exterior member (housing). Similarly, a bottom plate 109 constituting the exterior member is attached to a bottom surface of the front base 102. Thereby, the camera body 10a can withstand impacts from the outside of the camera body 10a.

The thermally conductive sheet 600 attached to the upper side of the image sensor unit 230 contacts the front base 102. The thermally conductive sheet 600 attached to the lower side of the image sensor unit 230 contacts the bottom plate 109. The thermally conductive sheet 600 attached to the left side of the image sensor unit 230 contacts the side plate 111. Thus, this embodiment can effectively radiate the heat generated by the image sensor unit 230, by bringing the thermally conductive sheet 600 into contact with each exterior member (housing) as a heat radiating member.

The thermally conductive sheet 600 has flexibility due to its Ω shape (curved shape). Therefore, according to this embodiment, the thermally conductive sheet 600 can follow the XY-directional swing control of the image sensor unit 230 without applying a load and maintain a contact state with each exterior member.

### Third Embodiment

Next, a third embodiment of the present disclosure will be described. The first and second embodiments have discussed examples of the heat radiation configuration of the image sensor 231 as a heat generator (electronic component). On the other hand, this embodiment will discuss an example heat radiation configuration of the EVF panel 401 as a heat generator (electronic component). Those elements in this embodiment, which are corresponding elements in the above embodiments, will be designated by the same reference numerals, and a detailed description thereof will be omitted.

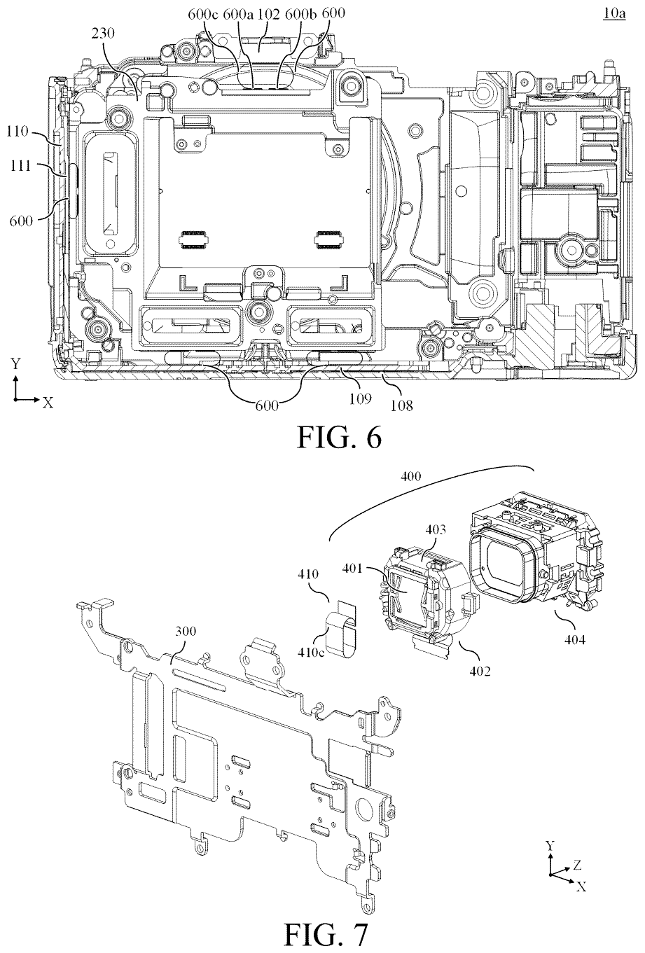

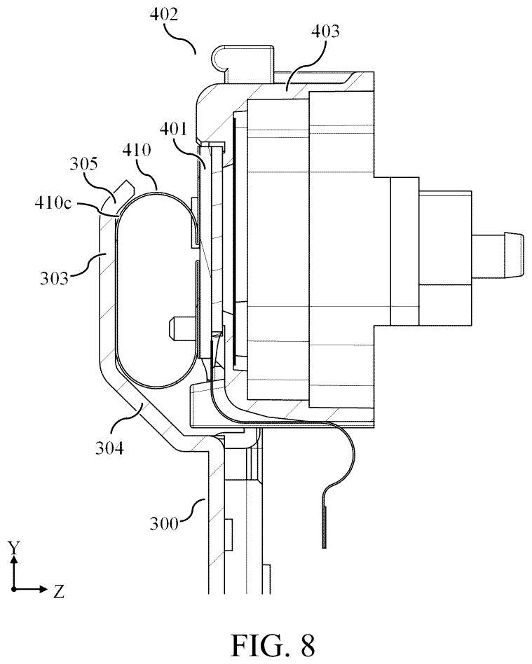

The heat radiating structure of the EVF panel 401 according to this embodiment will be described with reference to FIGS. 7 and 8. FIG. 7 is an exploded perspective view of the EVF unit (electronic apparatus) 400 according to this embodiment. FIG. 8 is a sectional view of the thermally conductive sheet 410.

The EVF unit 400 includes an EVF panel unit 402 and a lens unit 404. The EVF panel unit 402 has a diopter adjusting mechanism (not illustrated) and is displaceable in the Z-axis direction (optical axis direction) relative to the lens unit 404. The EVF panel unit 402 includes an EVF panel 401 and a panel holder 403 that holds the EVF panel 401. The EVF panel 401 is adhered and fixed to the panel holder 403.

The thermally conductive sheet 410 is a thermally conductive member that connects the EVF panel 401 and the contact surface 303 of the heat radiating sheet metal 300. The thermally conductive sheet 410 has an Ω shape (curved shape) when viewed from the X-axis direction. The thermally conductive sheet 410 is adhered to the EVF panel 401 with an adhesive agent (adhesive member) such as double-sided tape. The curved area 410c of the thermally conductive sheet 410 has a sufficient length so that it can contact a contact surface 303 of the heat radiating sheet metal 300 following the displacement amount of the EVF panel unit 402 in the Z-axis direction.

The heat radiating sheet metal 300 has inclined surfaces 304 and 305 configured to support the thermally conductive sheet 410. As a result, even if the thermally conductive sheet 410 is inclined in the Y-axis direction, it contacts the inclined surfaces 304 and 305 to maintain its Ω shape, and the thermally conductive sheet 410 is supported so that it is always in contact with the contact surface 303. The thermally conductive sheet 410 is likely to tilt in the −Y-axis direction, which is the gravity direction, when the image pickup apparatus is in the normal position state (when the upper side of the image pickup apparatus is disposed on the +Y-axis side (opposite the direction of the gravity direction)). Therefore, the heat radiating sheet metal 300 may have the inclined surface 304 on the −Y-axis side (gravity direction side), and may not have the inclined surface 305 on the +Y-axis side.

This embodiment using the thermally conductive sheet 410 applies no load to the adjustment in the Z-axis direction, and can effectively radiate the heat generated from the EVF panel 401 as a heat radiator to the heat radiating sheet metal 300.

The electronic apparatus according to each embodiment can secure a sufficient heat radiating path from the heat generator by stabilizing the contact surface between the heat generator and the thermally conductive sheet without impeding the displacement of the heat generator. Therefore, each embodiment can provide an electronic apparatus that can stably radiate heat from a displaceable heat generator.

While the disclosure has described example embodiments, it is to be understood that the disclosure is not limited to the example embodiments. The scope of the following claims is to be accorded the broadest interpretation so as to encompass all such modifications and equivalent structures and functions.

Each embodiment can provide an electronic apparatus that can stably radiate heat from a displaceable heat generator.

This application claims priority to Japanese Patent Application No. 2024-037311, which was filed on Mar. 11, 2024, and which is hereby incorporated by reference herein in its entirety.

What is claimed is:

1. An electronic apparatus comprising:
a heat generator;
a heat radiating member configured to radiate heat from the heat generator; and
a thermally conductive member disposed between the heat generator and the heat radiating member,
wherein the thermally conductive member has a first area, a second area, and a third area having a curved shape and disposed between the first area and the second area, and
wherein the first area and the second area of the thermally conductive member are attached to one of the heat generator and the heat radiating member.

2. The electronic apparatus according to claim 1, wherein the thermally conductive member is disposed so that the heat generator and the heat radiating member are in thermal contact.

3. The electronic apparatus according to claim 1, wherein the third area of the thermally conductive member includes an area having a cylindrical shape.

4. The electronic apparatus according to claim 1, wherein the third area of the thermally conductive member includes an area that contacts another of the heat generator and the heat radiating member.

5. The electronic apparatus according to claim 1, wherein the first area and the second area of the thermally conductive member are folded back relative to the third area.

6. The electronic apparatus according to claim 1, further comprising an adhesive member for adhering each of the first area and the second area to a part of the third area of the thermally conductive member.

7. The electronic apparatus according to claim 1, wherein one of the heat generator and the heat radiating member has an opening that allows at least a part of the thermally conductive member to escape in a case where the thermally conductive member is pressed in a direction in which the heat generator and the heat radiating member approach each other.

8. The electronic apparatus according to claim 1, wherein the thermally conductive member is a thermally conductive sheet attached to a surface orthogonal to an optical axis in each of the first area and the second area.

9. The electronic apparatus according to claim 1, wherein the heat generator is an imaging unit displaceable in an optical axis direction.

10. The electronic apparatus according to claim 1, wherein the heat radiating member includes a heat radiating sheet metal disposed at a position opposite to the heat generator.

11. The electronic apparatus according to claim 1, wherein the heat radiating member is an exterior member of the electronic apparatus.

12. The electronic apparatus according to claim 1, wherein the heat generator is an electronic viewfinder panel displaceable in an optical axis direction.

13. The electronic apparatus according to claim 12, wherein the heat radiating member has an inclined surface configured to support the thermally conductive member.

14. The electronic apparatus according to claim 13, wherein the inclined surface is formed on a gravity direction side of the thermally conductive member in a case where the electronic apparatus is in a normal position state.
